(19) United States
(12) Patent Application Publication
(10) Pub. No.: US 2026/0371803 A1
(43) Pub. Date: Nov. 19, 2026

(54) LIGHT-EMITTING DIODE CHIPS WITH VIA STRUCTURES THROUGH CONDUCTIVE CARRIER SUBMOUNTS AND RELATED METHODS

(71) Applicant: CreeLED, Inc., Durham, NC (US)

(72) Inventors: David Suich, Durham, NC (US); Michael Check, Holly Springs, NC (US); Andre Pertuit, Raleigh, NC (US); Joseph G. Sokol, Durham, NC (US); Robert Wilcox, Rolesville, NC (US); Colin Blakely, Raleigh, NC (US)

(21) Appl. No.: 19/208,799

(22) Filed: May 15, 2025

(51) Int. Cl. H10H 20/857; H10H 20/01; H10H 20/85

(52) U.S. Cl. CPC H10H 20/857; H10H 20/0364; H10H 20/8506

(57) ABSTRACT

Solid-state lighting devices including light-emitting diodes (LEDs) and more particularly LED chips with via structures through conductive carrier submounts and related methods are disclosed. An exemplary LED chip includes an active LED structure bonded to a carrier submount with an arrangement where both LED chip contacts are on a same side of the carrier submount, opposite the active LED structure. One LED chip contact is electrically coupled to the active LED structure by an electrically conductive path that includes the carrier submount, and the other LED chip contact is electrically coupled to the active LED structure by another electrically conductive path that includes a via structure that extends through the carrier submount.

### FIELD OF THE DISCLOSURE

The present disclosure relates to solid-state lighting devices including light-emitting diodes (LEDs) and more particularly to LED chips with via structures through conductive carrier submounts and related methods.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into active layers and corresponding recombination generates emissions of light. An active region may be fabricated, for example, from gallium nitride, gallium phosphide, aluminum nitride, and/or gallium arsenide-based materials and/or from organic semiconductor materials.

As advancements in modern LED technology progress, the art continues to seek improved LEDs and solid-state lighting devices having desirable illumination characteristics capable of overcoming challenges associated with conventional devices.

### SUMMARY

The present disclosure relates to solid-state lighting devices including light-emitting diodes (LEDs) and more particularly to LED chips with via structures through conductive carrier submounts and related methods. An exemplary LED chip includes an active LED structure bonded to a carrier submount with an arrangement where both LED chip contacts are on a same side of the carrier submount opposite the active LED structure. One LED chip contact is electrically coupled to the active LED structure by an electrically conductive path that includes the carrier submount, and the other LED chip contact is electrically coupled to the active LED structure by another electrically conductive path that includes a via structure that extends through the carrier submount.

In one aspect, an LED chip comprises: a carrier submount comprising a first side and a second side that is opposite the first side; an active LED structure on first side of the carrier submount, the active LED structure comprising an n-type layer, a p-type layer, and an active layer between the n-type layer and the p-type layer; a first contact pad on the second side of the carrier submount, the first contact pad electrically coupled to the active LED structure by a first electrically conductive path that includes the carrier submount; and a second contact pad on the second side of the carrier submount, the second contact pad electrically coupled to the active LED structure by a second electrically conductive path that includes an electrically conductive via extending through the carrier submount. The LED chip may further comprise a via passivation layer formed to electrically isolate the electrically conductive via from the carrier submount. In certain embodiments, the via passivation layer forms a first lateral extension between the active LED structure and the carrier submount. The LED chip may further comprise one or more bond metal layers between the active LED structure and the carrier submount, the one or more bond metal layers forming a portion of the first electrically conductive path wherein the first lateral extension is formed between the one or more bond metal layers and the electrically conductive via. In certain embodiments, the via passivation layer forms a second lateral extension between the second contact pad and the carrier submount. The LED chip may further comprise: one or more bond metal layers between the active LED structure and the carrier submount, the one or more bond metal layers forming a portion of the first electrically conductive path; and a passivation layer between the active LED structure and the carrier submount, the electrically conductive via extending through the one or more bond metal layers and the passivation layer. In certain embodiments, the via passivation layer and the passivation layer extend through an opening of the one or more bond metal layers. In certain embodiments, the electrically conductive via forms a first diameter within the carrier submount and a second diameter between the carrier submount and the active LED structure, wherein the second diameter is greater than the first diameter. In certain embodiments, the second diameter is graded from larger to smaller in a direction from the carrier submount to the active LED structure. In certain embodiments, the electrically conductive via is formed along a perimeter sidewall of the carrier submount. In certain embodiments, the electrically conductive via is one of a plurality of electrically conductive vias extending through the carrier submount and electrically coupled to the active LED structure. In certain embodiments, the electrically conductive via forms an elongated shape in a direction from one perimeter sidewall of the LED chip to another perimeter sidewall of the LED chip.

In another aspect, a method for fabricating an LED chip comprises: bonding an active LED structure to a first side of a carrier submount, the active LED structure comprising an n-type layer, a p-type layer, and an active layer between the n-type layer and the p-type layer; forming a first contact pad on a second side of the carrier submount, the second side being opposite the first side of the carrier submount, the first contact pad being electrically coupled to the active LED structure by a first electrically conductive path that includes the carrier submount; forming an electrically conductive via through the carrier submount; and forming a second contact pad on the second side of the carrier submount, the second contact pad electrically coupled to the active LED structure by a second electrically conductive path that includes the electrically conductive via. The method may further comprise: forming a first portion of the electrically conductive via, the first portion being electrically coupled to the active LED structure before bonding the active LED structure to the carrier submount; forming a second portion of the electrically conductive via in the carrier submount before bonding the active LED structure to the carrier submount; and electrically coupling the first portion of the electrically conductive via to the second portion of the electrically conductive via when the active LED structure is bonded to the carrier submount. In certain embodiments, bonding the active LED structure to the first side of the carrier submount comprises bonding a first bond metal layer that is on the active LED structure to a second bond metal layer that is on the carrier submount. The method may further comprise: forming a first opening portion in the first bond metal layer before bonding the active LED structure to the carrier submount; forming a second opening portion in the second bond metal layer before bonding the active LED structure to the carrier submount; and joining the first opening portion with the second opening portion to form an opening when the active LED structure is bonded to the carrier submount. The method may further comprise: filling the first opening portion with a passivation layer before bonding the active LED structure to the carrier submount; and filling the second opening portion with the passivation layer before bonding the active LED structure to the carrier submount; wherein forming the electrically conductive via comprises extending the electrically conductive via through the passivation layer to form the second electrically conductive path. In certain embodiments: the opening forms an air gap when the first opening portion and the second opening portion are joined together; and the electrically conductive via at least partially fills the opening such that the electrically conductive via forms a first diameter within the carrier submount and a second diameter between the carrier submount and the active LED structure, wherein the second diameter is greater than the first diameter. The method may further comprise forming a via passivation layer that electrically isolates the electrically conductive via from the carrier submount, the via passivation layer being formed within the opening in a position that is between the electrically conductive via and the first bond metal layer and between the electrically conductive via and the first bond metal layer. In certain embodiments, the electrically conductive via is formed along a perimeter sidewall of the carrier submount.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a cross-sectional view of a light-emitting diode (LED) chip with via structures according to principles of the present disclosure.

FIG. 1B is a cross-sectional view of the LED chip of FIG. 1A at a fabrication step before the active LED structure is bonded to the carrier submount.

FIG. 2A is a cross-sectional view of the LED chip that is similar to the LED chip of FIGS. 1A and 1B at a fabrication step for an alternative sequence where a via structure is formed after bonding the active LED structure to the carrier submount.

FIG. 2B is a cross-sectional view of the LED chip of FIG. 2A at a subsequent fabrication step after the active LED structure is bonded to the carrier submount.

FIG. 2C is a cross-sectional view of the LED chip of FIG. 2B at a subsequent fabrication step after the electrically conductive via and via passivation are formed.

FIG. 3A is a cross-sectional view of an LED chip that is similar to the LED chip of FIGS. 2A and 2B at a fabrication step for another alternative sequence where a via structure is formed after bonding the active LED structure to the carrier submount.

FIG. 3B is a cross-sectional view of the LED chip of FIG. 3A at a subsequent fabrication step after the active LED structure is bonded to the carrier submount.

FIG. 3C is a cross-sectional view of the LED chip of FIG. 3B at a subsequent fabrication step after the electrically conductive via and via passivation are formed.

FIG. 4A is a cross-sectional view of an LED chip that is similar to the LED chip of FIGS. 2A and 2B for embodiments where a via structure is formed along a perimeter sidewall of the carrier submount.

FIG. 4B is a cross-sectional view of the LED chip of FIG. 4A at a fabrication step at the wafer level and before singulation.

FIG. 5 is a top view of an LED chip that represents an elongated layout of the electrically conductive via for any of the embodiments described with respect to FIGS. 1A-3C.

FIG. 6 is a top view of an LED chip that represents an elongated layout of the electrically conductive via for the embodiments described with respect to FIGS. 4A and 4B.

FIG. 7 is a top view of an LED chip that represents another layout of the electrically conductive via for any of the embodiments described with respect to FIGS. 1A-3C.

FIG. 8 is a top view of an LED chip that represents another layout of the electrically conductive via for the embodiments described with respect to FIGS. 4A and 4B.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term "and/or" includes any and all combinations of one or more of the associated listed items.

It will be understood that when an element such as a layer, region, or substrate is referred to as being "on" or extending "onto" another element, it can be directly on or extend directly onto the other element or intervening elements may also be present. In contrast, when an element is referred to as being "directly on" or extending "directly onto" another element, there are no intervening elements present. Likewise, it will be understood that when an element such as a layer, region, or substrate is referred to as being "over" or extending "over" another element, it can be directly over or extend directly over the other element or intervening elements may also be present. In contrast, when an element is referred to as being "directly over" or extending "directly over" another element, there are no intervening elements present. It will also be understood that when an element is referred to as being "connected" or "coupled" to another element, it can be directly connected or coupled to the other element or intervening elements may be present. In contrast, when an element is referred to as being "directly connected" or "directly coupled" to another element, there are no intervening elements present.

Relative terms such as "below" or "above" or "upper" or "lower" or "horizontal" or "vertical" may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms "a," "an," and "the" are intended to include the plural forms as well, unless the context clearly indicates otherwise. It will be further understood that the terms "comprises," "comprising," "includes," and/or "including" when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting devices including light-emitting diodes (LEDs) and more particularly to LED chips with via structures through conductive carrier submounts and related methods. An exemplary LED chip includes an active LED structure bonded to a carrier submount with an arrangement where both LED chip contacts are on a same side of the carrier submount opposite the active LED structure. One LED chip contact is electrically coupled to the active LED structure by an electrically conductive path that includes the carrier submount, and the other LED chip contact is electrically coupled to the active LED structure by another electrically conductive path that includes a via structure that extends through the carrier submount.

An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include silicon carbide (SiC), organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SiC), aluminum nitride (AlN), and GaN.

Different embodiments of the active LED structure can emit different wavelengths of light depending on the composition of the active layer and n-type and p-type layers. In certain embodiments, the active LED structure may emit blue light with a peak wavelength range of approximately 430 nanometers (nm) to 480 nm. In other embodiments, the active LED structure may emit green light with a peak wavelength range of 500 nm to 570 nm. In other embodiments, the active LED structure may emit red light with a peak wavelength range of 600 nm to 650 nm. In certain embodiments, the active LED structure may emit light with a peak wavelength in any area of the visible spectrum, for example peak wavelengths primarily in a range from 400 nm to 700 nm.

In certain embodiments, the active LED structure may be configured to emit light that is outside the visible spectrum, including one or more portions of the ultraviolet (UV) spectrum, the infrared (IR) or near-IR spectrum. The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications. Near-IR and/or IR wavelengths for LED structures of the present disclosure may have wavelengths above 700 nm, such as in a range from 750 nm to 1100 nm, or more.

The LED chip can also be covered with one or more lumiphoric or other conversion materials, such as phosphors, such that at least some of the light from the LED chip is absorbed by the one or more phosphors and is converted to one or more different wavelength spectra according to the characteristic emission from the one or more phosphors. In some embodiments, the combination of the LED chip and the one or more phosphors emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof. Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, multiple different (e.g., compositionally different) lumiphoric materials arranged to produce different peak wavelengths may be arranged to receive emissions from one or more LED chips. In some embodiments, one or more phosphors may include yellow phosphor (e.g., YAG:Ce), green phosphor (e.g., LuAg:Ce), and red phosphor (e.g., Ca_{i-x-y}SrₓEu_{y}AlSiN₃) and combinations thereof. One or more lumiphoric materials may be provided on one or more portions of an LED chip and/or a submount in various configurations.

Light emitted by the active layer or region of an LED chip typically is initiated in multiple directions. For directional applications, internal mirrors or external reflective surfaces may be employed to redirect as much light as possible toward a desired emission direction. Internal mirrors may include single or multiple layers. Some multi-layer mirrors include a metal reflector layer and a dielectric reflector layer, wherein the dielectric reflector layer is arranged between the metal reflector layer and a plurality of semiconductor layers. A passivation layer is arranged between the metal reflector layer and first and second electrical contacts, wherein the first electrical contact is arranged in conductive electrical communication with a first semiconductor layer, and the second electrical contact is arranged in conductive electrical communication with a second semiconductor layer. For single or multi-layer mirrors including surfaces exhibiting less than 100% reflectivity, some light may be absorbed by the mirror. Additionally, light that is redirected through the active LED structure may be absorbed by other layers or elements within the LED chip.

As used herein, a layer or region of a light-emitting device may be considered to be "transparent" when at least 80% of emitted radiation that impinges on the layer or region emerges through the layer or region. Moreover, as used herein, a layer or region of an LED is considered to be "reflective" or embody a “mirror” or a "reflector" when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure may be useful for LED chips having a variety of geometries, such as vertical geometry. A vertical geometry LED chip typically includes anode and cathode connections on opposing sides or faces of the LED chip. In certain embodiments, a vertical geometry LED chip may also include a growth substrate that is arranged between the anode and cathode connections. In certain embodiments, LED chip structures may include a carrier submount and where the growth substrate is removed. In still further embodiments, any of the principles described may also be applicable to flip-chip structures where anode and cathode connections are made from a same side of the LED chip for flip-chip mounting to another surface.

According to aspects of the present disclosure, an exemplary LED chip includes an active LED structure bonded to a carrier submount that is electrically conductive. A growth substrate used to epitaxially grow the active LED structure is removed such that a top surface of the epitaxially grown active LED structure forms a primary light-extracting face of the LED chip. Accordingly, the LED chip forms a generally two-dimensional emitter where a substantial portion and/or a majority of light exits the top surface of the active LED structure without propagating through a growth substrate. This may also provide thermal performance improvements by positioning the active LED structure in close proximity to the carrier submount. In conventional LED chips that have a conductive carrier submount, at least one contact is typically positioned on a top side of the LED chip, thereby positioning a light-absorbing wire bond in light emitting pathways while also requiring additional etching steps for the active LED structure to facilitate the top side electrical connection. According to aspects of the present disclosure, an LED chip structure with a carrier submount is formed where both chip contacts are positioned on a bottom side of the carrier submount, opposite the active LED structure. Such a structure may be well-suited for use in applications that employ flip-chip LED structures. Via structures include through vias that provide at least one electrically conductive pathway through the carrier submount that is electrically isolated from the carrier submount. Vias may be formed by various processes, such as drilling, at various stages of LED chip fabrication as described in greater detail below. The other electrically conductive pathway may employ the carrier submount.

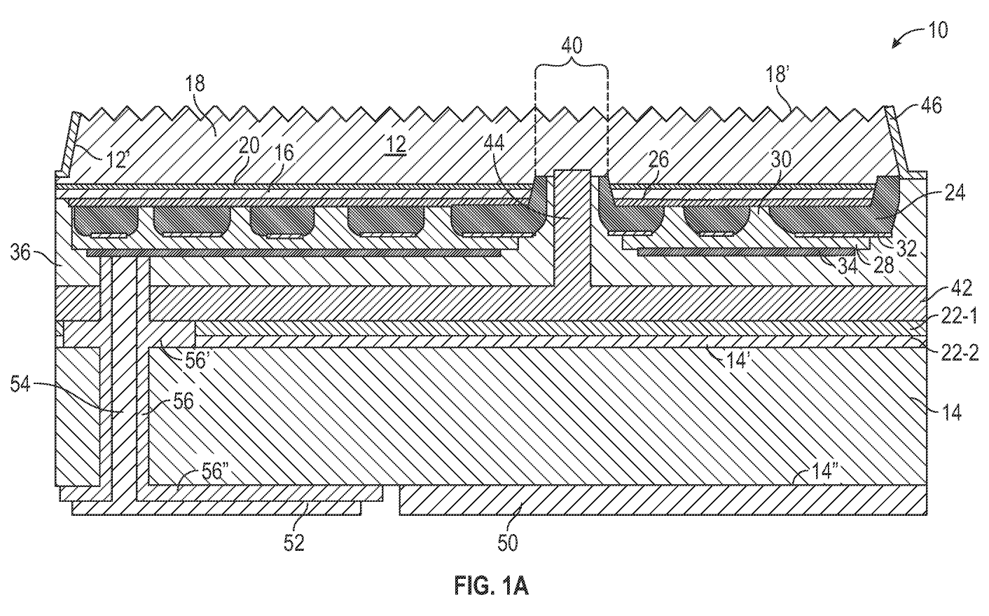

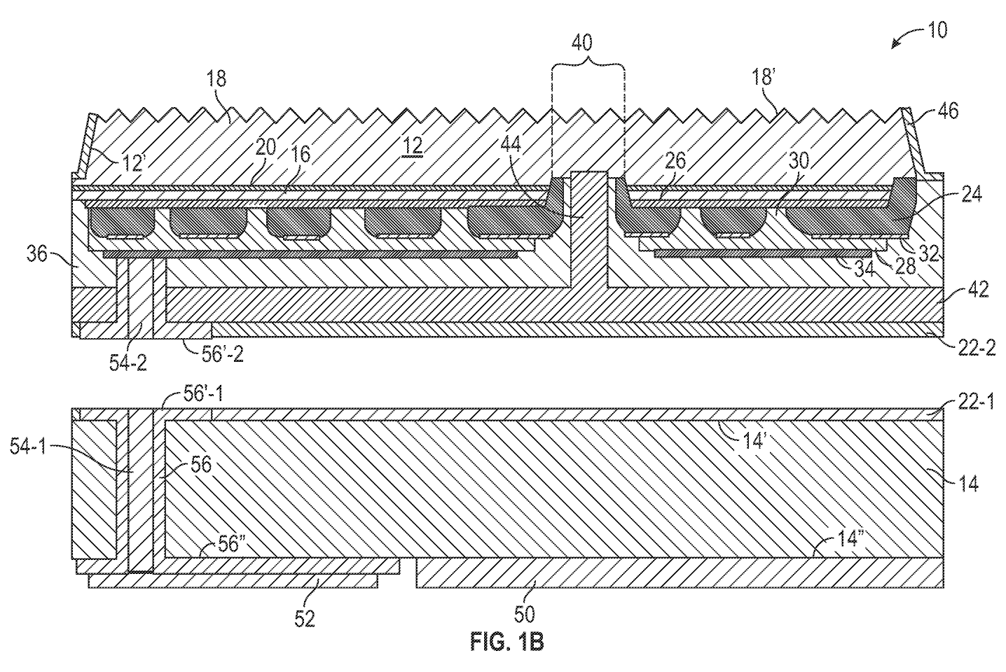

FIG. 1A is a cross-sectional view of an LED chip 10 with via structures according to principles of the present disclosure. The LED chip 10 includes an active LED structure 12 formed on a carrier submount 14. The active LED structure 12 generally refers to portions of the LED chip 10 that include semiconductor layers, such as epitaxial semiconductor layers, that form a structure that generates light when electrically activated. The active LED structure 12 is formed on and supported by a first side 14’ of the carrier submount 14. The carrier submount 14 may comprise various electrically conductive materials, with a suitable material being silicon or doped silicon. In certain embodiments, the carrier submount 14 comprises an electrically conductive material such that the carrier submount 14 is part of electrically conductive connections to the active LED structure 12.

The active LED structure 12 may generally comprise a p-type layer 16, an n-type layer 18, and an active layer 20 arranged between the p-type layer 16 and the n-type layer 18. The active LED structure 12 may include many additional layers such as, but not limited to, buffer layers, nucleation layers, super lattice structures, undoped layers, cladding layers, contact layers, current-spreading layers, and light extraction layers and elements. In various embodiments, the active layer 20 may comprise a single quantum well, a multiple quantum well, a double heterostructure, or super lattice structures. In FIG. 1A, the p-type layer 16 is arranged between the active layer 20 and the carrier submount 14 such that the p-type layer 16 is closer to the carrier submount 14 than the n-type layer 18. The active LED structure 12 may initially be formed by epitaxially growing or depositing the n-type layer 18, the active layer 20, and the p-type layer 16 sequentially on a growth substrate. The active LED structure 12 may then be flipped and bonded to the carrier submount 14 by way of one or more bond metal layers 22-1, 22-2 and the growth substrate is removed. In this manner, a top surface 18’ of the n-type layer 18 forms a primary light-extracting face of the LED chip 10. In certain embodiments, the top surface 18′ may comprise a textured or patterned surface for improving light extraction. In other embodiments, the doping order may be reversed such that the n-type layer 18 is arranged between the active layer 20 and the carrier submount 14. As mentioned above, the active LED structure 12 is bonded to the carrier submount 14 by way of one or more of the bond metal layers 22-1, 22-2. During bonding, such as a eutectic bonding process, the bond metal layers 22-1, 22-2 are heated to collectively form bonding materials (e.g., one or more eutectic alloys) between the active LED structure 12 and the carrier submount 14. Exemplary bond metal layers 22-1, 22-2 may include gold (Au), tin (Sn), nickel (Ni), palladium (Pd), titanium (Ti), tungsten (W), and alloys thereof.

The LED chip 10 may include a first reflective layer 24 provided on the p-type layer 16. In certain embodiments, a current spreading layer 26 may be provided between the p-type layer 16 and the first reflective layer 24. The current spreading layer 26 may include a thin layer of a transparent conductive oxide such as indium tin oxide (ITO) or a thin metal layer such as platinum (Pt), although other materials may be used. The first reflective layer 24 may comprise many different materials and preferably comprises a material that presents an index of refraction step with the material of the active LED structure 12 to promote total internal reflection (TIR) of light generated from the active LED structure 12. Light that experiences TIR is redirected without experiencing absorption or loss and can thereby contribute to useful or desired LED chip emission. In certain embodiments, the first reflective layer 24 comprises a material with an index of refraction lower than the index of refraction of the active LED structure 12 material. The first reflective layer 24 may comprise many different materials, with some having an index of refraction less than 2.3, while others can have an index of refraction less than 2.15, less than 2.0, and less than 1.5. In certain embodiments, the first reflective layer 24 comprises a dielectric material, such as silicon dioxide (SiO₂)and/or silicon nitride (SiN). It is understood that many dielectric materials can be used such as SiN, SiNₓ, Si₃N₄, Si, germanium (Ge), SiO₂, SiOx, titanium dioxide (TiO₂), tantalum pentoxide (Ta₂O₅)_{,} ITO, magnesium oxide (MgOx), zinc oxide (ZnO), and combinations thereof. In certain embodiments, the first reflective layer 24 may include multiple alternating layers of different dielectric materials, e.g., alternating layers of SiO₂ and SiN that symmetrically repeat or are asymmetrically arranged. Some Group III nitride materials such as GaN can have an index of refraction of approximately 2.4, SiO₂ can have an index of refraction of approximately 1.48, and SiN can have an index of refraction of approximately 1.9. Embodiments with the active LED structure 12 comprising GaN and the first reflective layer 24 comprising SiO₂ may form a sufficient index of refraction step between the two to allow for efficient TIR of light. The first reflective layer 24 may have different thicknesses depending on the type of materials used, with some embodiments having a thickness of at least 0.2 microns (μm). In some embodiments, the first reflective layer 24 can have a thickness in the range of 0.2 μm to 0.7 μm, while in some embodiments the thickness can be approximately 0.5 μm. As used herein, the first reflective layer 24 may also be referred to as a dielectric reflective layer and the terms may be used interchangeably.

The LED chip 10 may further include a second reflective layer 28 that is on the first reflective layer 24 such that the first reflective layer 24 is arranged between the active LED structure 12 and the second reflective layer 28. The second reflective layer 28 may include a metal layer that is configured to reflect light from the active LED structure 12 that may pass through the first reflective layer 24. As used herein, the second reflective layer 28 may also be referred to as a metal reflective layer and the terms may be used interchangeably. The second reflective layer 28 may comprise many different materials such as Ag, Au, Al, Ni, Ti, or combinations thereof. The second reflective layer 28 may have different thicknesses depending on the type of materials used, with some embodiments having a thickness of at least 0.1 μm, or in a range from 0.1 μm to 0.7 μm, or in a range from 0.1 um to 0.5 um, or in a range from 0.1 μm to 0.3 μm, or up to about 1.5 μm. As illustrated, the second reflective layer 28 may include or form one or more reflective layer interconnects 30 that provide an electrically conductive path through the first reflective layer 24. In this manner, the one or more reflective layer interconnects 30 may extend through an entire thickness of the first reflective layer 24. In certain embodiments, the second reflective layer 28 is a metal reflective layer and the reflective layer interconnects 30 comprise reflective layer metal vias.

Accordingly, the first reflective layer 24, the second reflective layer 28, and the reflective layer interconnects 30 form a reflective structure of the LED chip 10 that is on the p-type layer 16. As such, the reflective structure may comprise a dielectric reflective layer and a metal reflective layer as disclosed herein. In certain embodiments, the reflective layer interconnects 30 comprise the same material as the second reflective layer 28 and are formed at the same time as the second reflective layer 28. In other embodiments, the reflective layer interconnects 30 may comprise a different material than the second reflective layer 28. Certain embodiments may also comprise an adhesion layer 32 that is positioned at one or more interfaces between the first reflective layer 24 and the second reflective layer 28 to promote improved adhesion therebetween. Many different materials can be used for the adhesion layer 32, such as titanium oxide (TiO, TiO₂), titanium oxynitride (TiON, TiₓO_{y}N), tantalum oxide (TaO, Ta₂O₅), tantalum oxynitride (TaON), aluminum oxide (AlO, AlₓO_{y}) or combinations thereof, with a preferred material being TiON, AlO, or AlxOy. In certain embodiments, the adhesion layer comprises AlₓO_{y}, where 1≤x≤4 and 1≤y≤6. In certain embodiments, the adhesion layer comprises AlₓO_{y}, where x=2 and y=3, or Al₂O₃. The adhesion layer 32 may be deposited by electron beam deposition that may provide a smooth, dense, and continuous layer without notable variations in surface morphology. The adhesion layer 32 may also be deposited by sputtering, chemical vapor deposition, plasma enhanced chemical vapor deposition, or atomic layer deposition (ALD). In still further embodiments, the adhesion layer 32 may comprise a discontinuous layer.

The LED chip 10 may also comprise a barrier layer 34 on the second reflective layer 28 to prevent migration of material of the second reflective layer 28, such as Ag, to other layers. Preventing this migration helps the LED chip 10 maintain efficient operation throughout its lifetime. The barrier layer 34 may comprise an electrically conductive material, with suitable materials including but not limited Ti, Pt, Ni, Au, W, and combinations or alloys thereof.

A passivation layer 36 is included on the second reflective layer 28 in a position that is between the second reflective layer 28 and the carrier submount 14. The passivation layer 36 protects and provides electrical insulation for the LED chip 10 and can comprise many different materials, such as a dielectric material including but not limited to silicon nitride. In certain embodiments, the passivation layer 36 is a single layer, and in other embodiments, the passivation layer 36 comprises a plurality of layers. In certain embodiments, the passivation layer 36 may include one or more metal-containing interlayers arranged or embedded therein that may function as a crack stop layer for any cracks that may propagate through the passivation layer 36 as well as an additional light reflective layer.

In FIG. 1A, the active LED structure 12 forms a first recess 40, or opening, that extends through the p-type layer 16, the active layer 20, and a portion of the n-type layer 18. The first recess 40 may be formed by a subtractive material process, such as etching, that is applied to the active LED structure 12 before bonding with the carrier submount 14. As used herein, the first recess 40 may also be referred to as an active LED structure opening. As illustrated, a portion of the first reflective layer 24 is arranged to cover sidewall surfaces of the p-type layer 16, the active layer 20, and the n-type layer 18 within the first recess 40. The passivation layer 36 extends along the first reflective layer 24 in the first recess 40 and is arranged on a surface of the n-type layer 18. The LED chip 10 further includes an n-contact metal layer 42 that is arranged on the passivation layer 36 and across the LED chip 10. At the first recess 40, the n-contact metal layer 42 extends into the first recess 40 to form an n-contact interconnect 44, which may be referred to as an n-contact via. In this manner, the first recess 40 may be defined where portions of the n-contact metal layer 42, the n-contact interconnect 44, the passivation layer 36, and the first reflective layer 24 extend into the active LED structure 12. As such, the n-contact metal layer 42 and the n-contact interconnect 44 may be integrally formed to provide an electrical connection to the n-type layer 18 through the first recess 40. In other embodiments, the n-contact metal layer 42 and the n-contact interconnect 44 may be separately formed and may comprise the same or different materials. In certain embodiments, the n-contact metal layer 42 and the n-contact interconnect 44 comprise a single layer or a plurality of layers that include conductive metals, such as one or more of Al, Ti, and alloys thereof.

One or more top passivation layers 46 may be provided on one or more top or side surfaces of the n-type layer 18 for additional electrical insulation. The top passivation layer 46 may comprise separate layers of a continuous layer of dielectric material, such as silicon nitride. In FIG. 1A, the top passivation layer 46 is arranged to cover sidewalls 12’ of the active LED structure 12.

The LED chip 10 includes a first contact 50 which may also be referred to as a first contact pad, and a second contact 52 which may also be referred to as second contact pad. The first contact 50 and the second contact 52 may both be formed on a second side 14’’ of the carrier submount 14 that is opposite the first side 14’. In the example of FIG. 1A, the first contact 50 is electrically coupled to the n-type layer 18 of the active LED structure 12 by way of a first electrically conductive path that includes the carrier submount 14. The first electrically conductive path may further include the bond metal layers 22-1, 22-2, the n-contact metal layer 42, and the n-contact interconnect 44. While a single n-contact interconnect 44 is shown, the LED chip 10 may include a plurality of n-contact interconnects 44. Since the first contact 50 is electrically coupled to the n-type layer 18, the first contact 50 may also be referred to as an n-contact or an n-contact pad for the embodiments of FIG. 1A.

The second contact 52 is electrically coupled to the p-type layer 16 of the active LED structure 12 by way of an electrically conductive via 54. The electrically conductive via 54 may form a through via that extends entirely through the carrier submount 14, the bond metal layers 22-1, 22-2, the n-contact metal layer 42, and the passivation layer 36. To ensure electrical isolation from the carrier submount 14, a via passivation layer 56 is provided between the electrically conductive via 54 and the carrier submount 14. The via passivation layer 56 may further extend through the bond metal layers 22-1, 22-2 and the n-contact metal layer 42. A second electrically conductive path is thereby formed between the second contact 52 and the p-type layer 16 that includes the electrically conductive via 54, the barrier layer 34, the second reflective layer 28, and the current spreading layer 26. Since the second contact 52 is electrically coupled to the p-type layer 16, the second contact 52 may also be referred to as a p-contact or a p-contact pad for the embodiments of FIG. 1A.

As illustrated, the via passivation layer 56 may form a first lateral extension 56’ that laterally extends away from the electrically conductive via 54 in a position that is between the active LED structure 12 and the carrier submount 14. This first lateral extension 56’ may form an insulating buffer that is between the bond metal layers 22-1, 22-2 and the electrically conductive via 54, and prevents electrical shorting during the bonding process. The first lateral extension 56’ may effectively form a ring structure around the electrically conductive via 54. In certain embodiments, the via passivation layer 56 may form a second lateral extension 56’’ on the second side 14’’ of the carrier submount 14 to electrically insulate the second contact 52 from the carrier submount 14.

As described above with respect to FIG. 1A, the LED chip 10 includes an active LED structure 12 bonded to a carrier submount 14. Since the growth substrate used to epitaxially grow the active LED structure 12 is removed, the top surface 18’ of the n-type layer 18 forms a primary light-extracting face of the LED chip 10 to form a generally two-dimensional emitter where a substantial portion and/or a majority of light exits the top surface 18’. This may advantageously provide suitable thermal performance by virtue of the thermal conductivity of the carrier submount 14 and its close proximity to the active LED structure 12. Since the first and second contacts 50, 52 are both formed on the second side 14’’, or bottom side, of the carrier submount 14, the LED chip 10 may be well-suited for use in applications that employ flip-chip LED structures. In conventional LED chips that have a conductive carrier submount, one of the contacts is typically positioned on a top side of such LED chips, thereby positioning a light-absorbing wire bond in light-emitting pathways above the LED chip while also requiring additional etching steps for the active LED structure to facilitate the top side electrical connection. By positioning both the first contact 50 and the second contact 52 on the bottom side of the LED chip 10, no wire bonds are needed to electrically connect the LED chip 10, and a larger area of the active LED structure 12 may be preserved for increased light emissions.

FIG. 1B is a cross-sectional view of the LED chip 10 of FIG. 1A at a fabrication step before the active LED structure 12 is bonded to the carrier submount 14. As illustrated, one bonding metal layer 22-1 may be formed on the carrier submount 14 and the other bonding metal layer 22-2 may be formed on the active LED structure 12. In certain embodiments, the first lateral extension 56’ of the via passivation layer 56 may be initially split into a first portion 56’-1 on the carrier submount 14 and a second portion 56’-2 on the active LED structure 12. In a similar manner, the electrically conductive via 54 may be split into a first portion 54-1 in the carrier submount 14 and a second portion 54-2 proximate the active LED structure 12. During bonding for the bonding metal layers 22-1, 22-2, the first and second via portions 54-1, 54-2 may be concurrently bonded together. The first and second portions 56’-1, 56’-2 of the via passivation layer 56 may effectively form insulating buffer structures that permit some increased alignment tolerances between the first and second via portions 54-1, 54-2. This allows some misalignment between the first and second via portions 54-1, 54-2 while ensuring electrical connections therebetween and electrical isolation with the carrier submount 14 and the bond metal layers 22-1, 22-2.

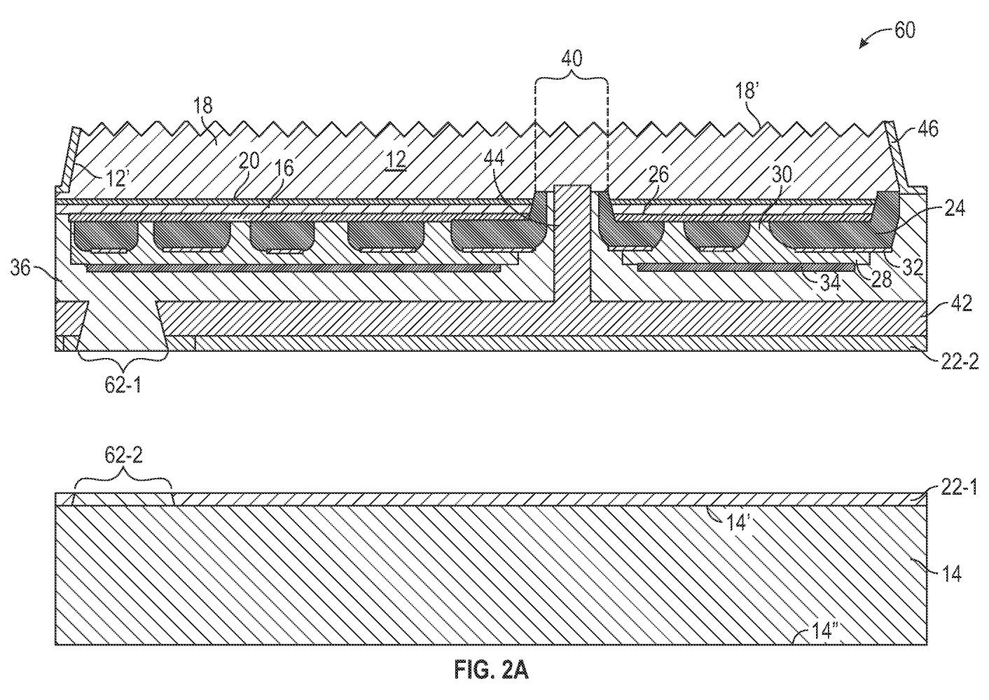

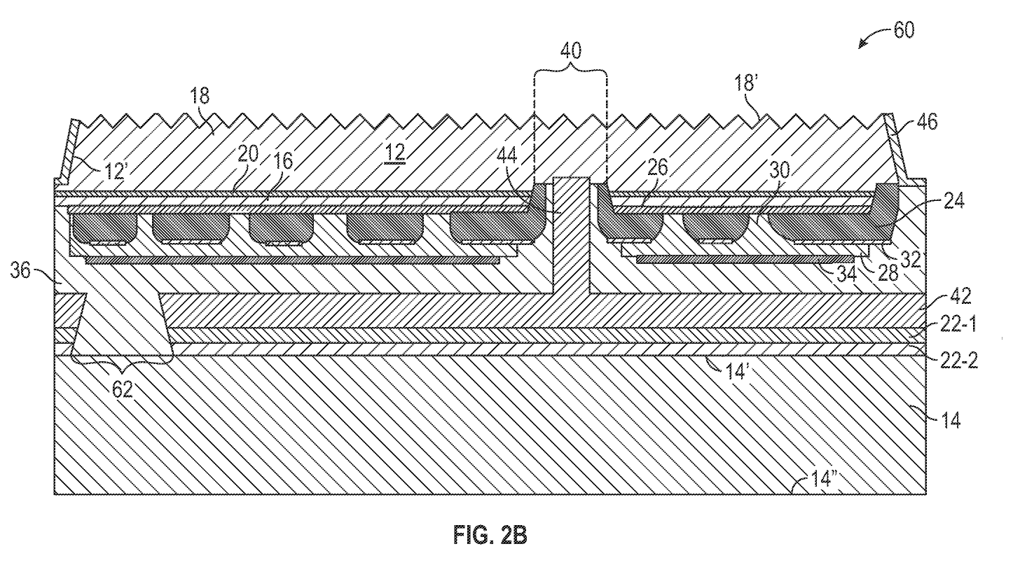

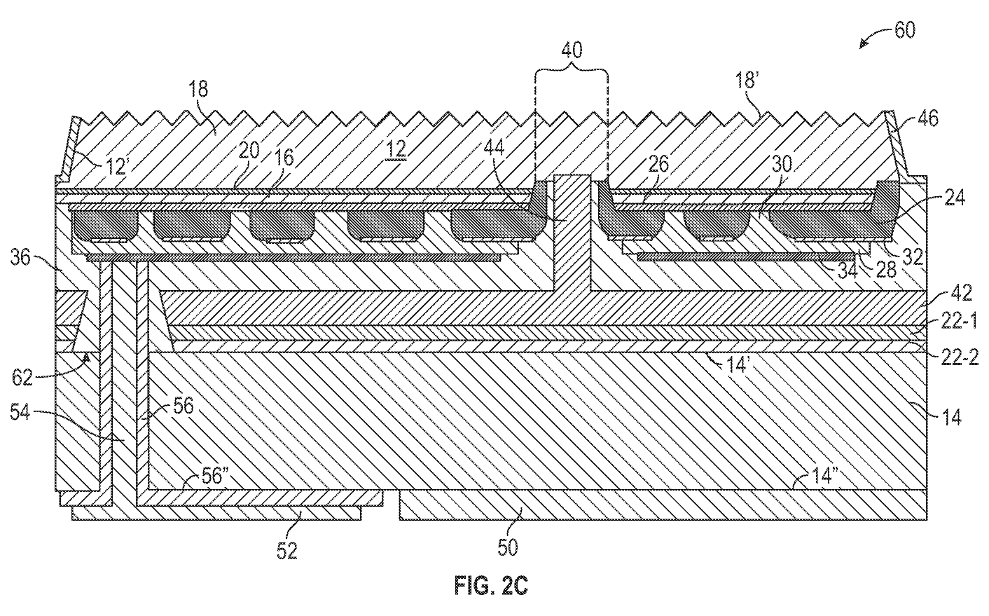

FIGS. 2A-2C are cross-sectional views of an LED chip 60 that is similar to the LED chip 10 of FIGS. 1A and 1B at various fabrication steps for an alternative sequence where a via structure is formed after bonding the active LED structure 12 to the carrier submount 14.

FIG. 2A is a cross-sectional view of the LED chip 60 at a fabrication step before the active LED structure 12 is bonded to the carrier submount 14. Before bonding, a first opening portion 62-1 is formed through the bond metal layer 22-1 and the n-contact metal layer 42. The first opening portion 62-1 is filled with the passivation layer 36 such that the passivation layer 36 is continuous from the first opening portion 62-1 to the barrier layer 34. A second opening portion 62-1 is formed through the bond metal layer 22-2 of the carrier submount 14 in a position that is aligned with the first opening portion 62-1. A portion of the passivation layer 36 is also formed to fill the second opening portion 62-1. By way of example, the first and second opening portions 62-1, 62-2 may be formed by etching, thereby forming angled sidewalls such that an opening 62 increases in diameter in a direction from the active LED structure 12 toward the carrier submount 14.

FIG. 2B is a cross-sectional view of the LED chip 60 of FIG. 2A at a subsequent fabrication step after the active LED structure 12 is bonded to the carrier submount 14. With suitable alignment, the first and second opening portions 62-1, 62-2 of FIG. 2A are joined together to form a single opening 62 that extends from the carrier submount 14 to the barrier layer 34. Additionally, the opening 62 is filled with the passivation layer 36. The opening 62 effectively forms a window in the bond metal layers 22-1, 22-2 to permit visibility and suitable alignment of the electrically conductive via 54 of FIG. 2C.

FIG. 2C is a cross-sectional view of the LED chip 60 of FIG. 2B at a subsequent fabrication step after the electrically conductive via 54 and via passivation layer 56 are formed. The electrically conductive via 54 may be formed by drilling through the carrier submount 14 and the passivation layer 36 in a position aligned through the opening 62, thereby exposing a surface of the barrier layer 34. As with the LED chip 10 of FIGS. 1A and 1B, the first contact pad 50 is electrically coupled to the active LED structure 12 by a first electrically conductive path that includes carrier submount 14, and the second contact pad 52 is electrically coupled to the active LED structure 12 by a second electrically conductive path that includes the electrically conductive via 54 extending through the carrier submount 14 and the passivation layer 36. In the embodiment of FIG. 2C, the passivation layer 36 and the via passivation layer 56 form a two-layer passivation structure extending through the opening 62 and along the sidewalls of the electrically conductive via 54 that extend through the bond metal layers 22-1, 22-2.

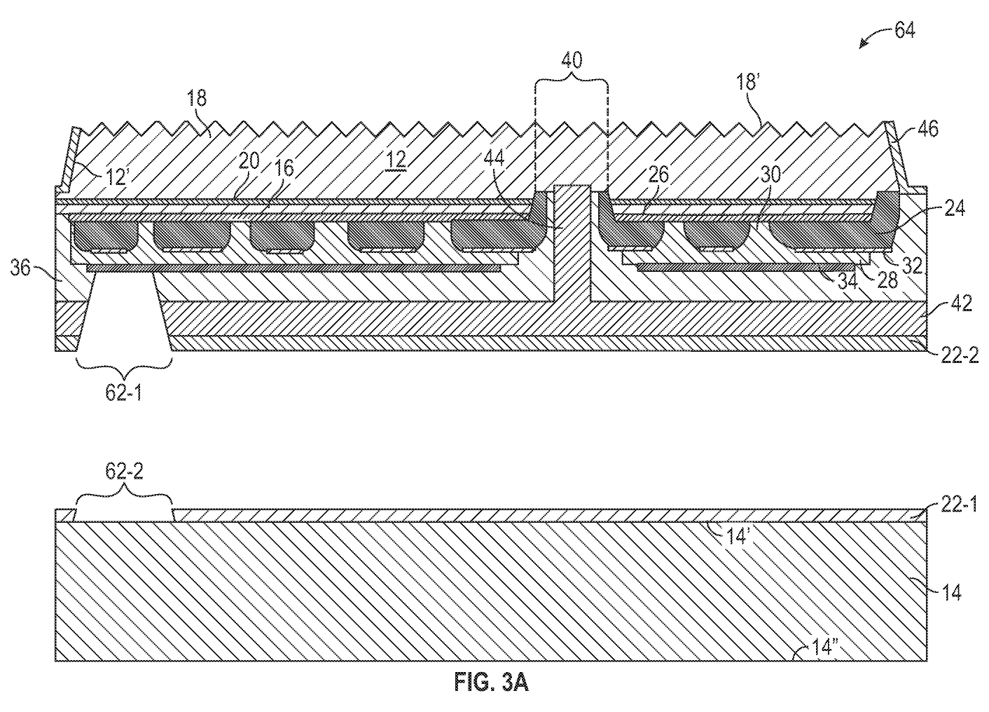

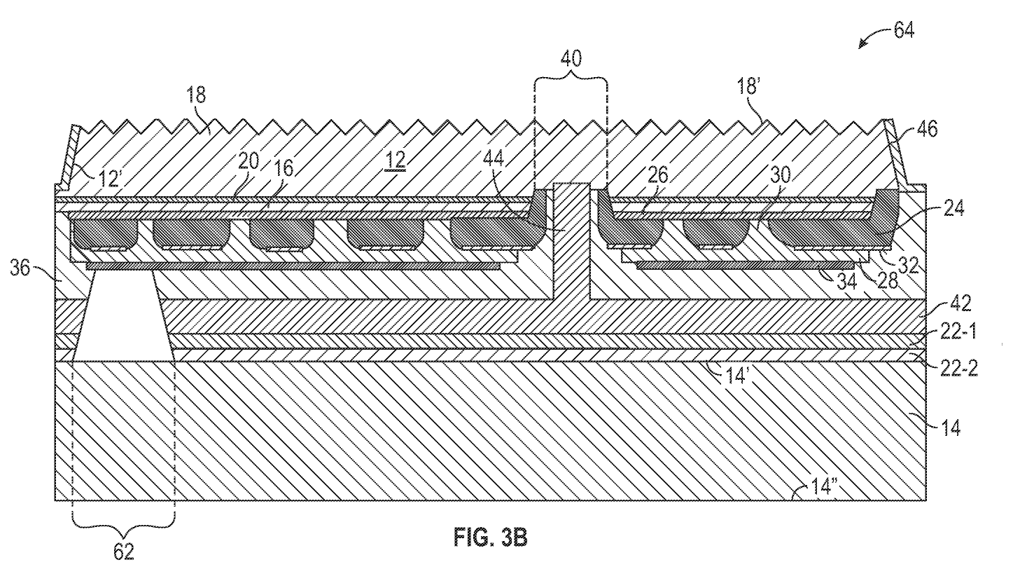

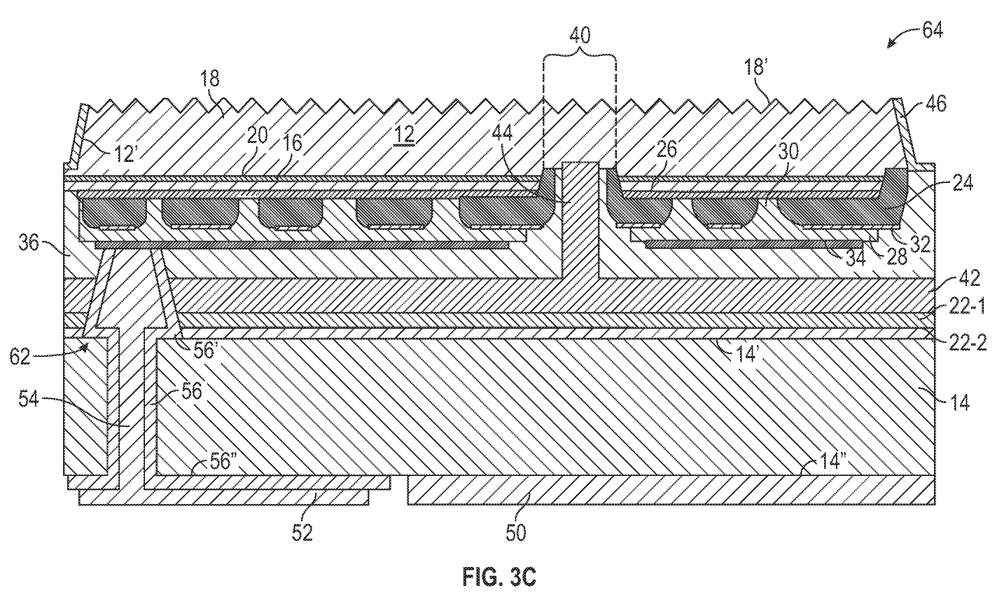

FIGS. 3A-3C are cross-sectional views of an LED chip 64 that is similar to the LED chip 60 of FIGS. 2A and 2B at various fabrication steps for another alternative sequence where a via structure is formed after bonding the active LED structure 12 to the carrier submount 14.

FIG. 3A is a cross-sectional view of the LED chip 64 at a fabrication step before the active LED structure 12 is bonded to the carrier submount 14. Before bonding, the first opening portion 62-1 is formed through the bond metal layer 22-1 and the n-contact metal layer 42. The second opening portion 62-1 is formed through the bond metal layer 22-2 of the carrier submount 14 in a position that is aligned with the first opening portion 62-1. For the LED chip 64, the first opening portion 62-1 and the second opening portion 62-2 are left open as air gaps. By way of example, the first and second opening portions 62-1, 62-2 may be formed by etching, thereby forming angled sidewalls such that the opening 62 increases in diameter in a direction from the active LED structure 12 toward the carrier submount 14.

FIG. 3B is a cross-sectional view of the LED chip 64 of FIG. 3A at a subsequent fabrication step after the active LED structure 12 is bonded to the carrier submount 14. With suitable alignment, the first and second opening portions 62-1, 62-2 of FIG. 3A are joined together to form a single opening 62 that extends from the carrier submount 14 to the barrier layer 34. For the LED chip 64, the opening 62 forms an air gap that extends from the carrier submount 14 to the barrier layer 34. The opening 62 effectively forms a window in the bond metal layers 22-1, 22-2 and the passivation layer 36 to permit further visibility and suitable alignment of the electrically conductive via 54 of FIG. 3C.

FIG. 3C is a cross-sectional view of the LED chip 64 of FIG. 3B at a subsequent fabrication step after the electrically conductive via 54 and via passivation layer 56 are formed. The electrically conductive via 54 may be formed by drilling through the carrier submount 14 to the opening 62, thereby exposing a surface of the barrier layer 34. Since the opening 62 is an air gap, the drilling may be stopped after drilling through the carrier submount 14, thereby reducing and/or preventing drilling damage on the barrier layer 34. As with the LED chip 10 of FIGS. 1A and 1B, the first contact pad 50 is electrically coupled to the active LED structure 12 by a first electrically conductive path that includes carrier submount 14, and the second contact pad 52 is electrically coupled to the active LED structure 12 by a second electrically conductive path that includes the electrically conductive via 54 extending through the carrier submount 14 and the passivation layer 36. In the embodiment of FIG. 3C, the via passivation layer 56 may conformally coat the angled sidewalls of the opening 62. The electrically conductive via 54 may then fill the remainder of the opening 62. Accordingly, the electrically conductive via 54 may be formed with a first diameter within the carrier submount 14 and a second diameter that is between the carrier submount 14 and the active LED structure 12. Moreover, the second diameter may be graded from larger to smaller in a direction from the carrier submount 14 to the active LED structure 12 according to the taper of the opening 62.

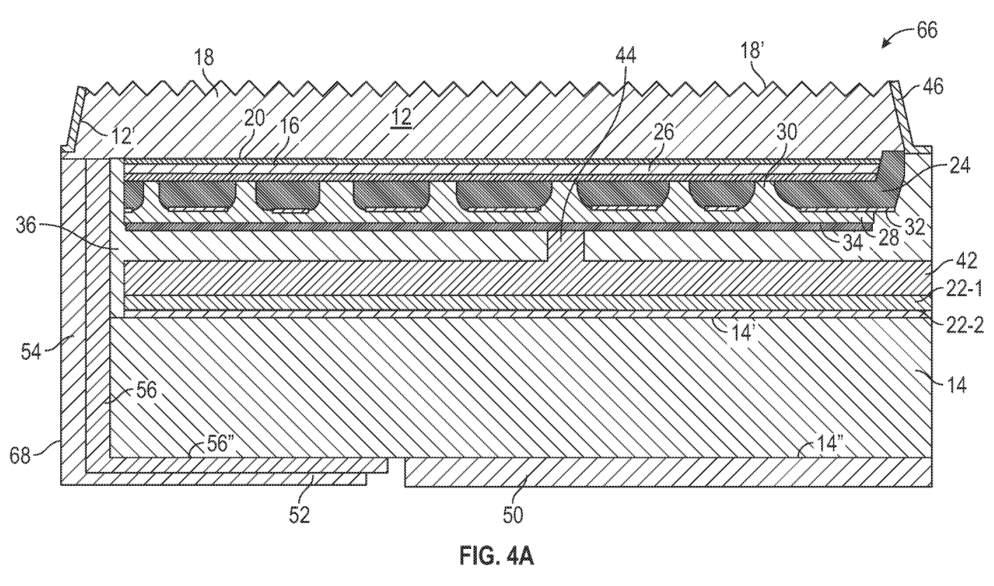

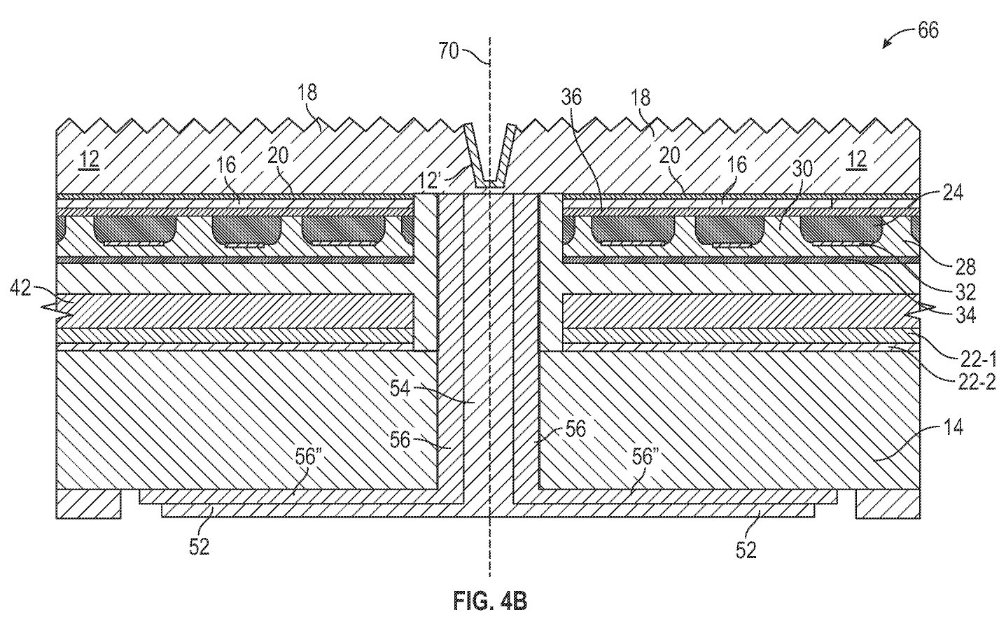

FIGS. 4A and 4B are cross-sectional views of an LED chip 66 that is similar to the LED chip 60 of FIGS. 2A and 2B at various fabrication steps for another alternative sequence where a via structure is formed along a perimeter sidewall 68 of the carrier submount 14.

FIG. 4A is a cross-sectional view of the LED chip 66 with the electrically conductive via 54 formed along the perimeter sidewall 68 of the carrier submount 14. The perimeter sidewall 68 may extend along portions of the active LED structure 12 with electrical isolation provided by the passivation layer 36. By moving the electrically conductive via 54 to the perimeter sidewall 68, less area of the active LED structure 12 may need to be removed to facilitate the electrically conductive pathway between the second contact 52 and the active LED structure 12. As will be described below with respect to FIG. 4B, the electrically conducive via 54 may be formed in a street (i.e., 70 of FIG. 4B) between neighboring LED chip regions at a wafer level. After singulation through the street, the electrically conductive via 54 is formed along the perimeter sidewall 68 of the carrier submount 14 with the via passivation layer 56 between the electrically conductive via 54 and the carrier submount 14, bond metal layers 22-1, 22-2, barrier layer 34, second reflective layer 28, and portions of the active LED structure 12 (i.e., the p-type layer 16 and the active layer 20).

FIG. 4B is a cross-sectional view of the LED chip 66 of FIG. 4A at a fabrication step at the wafer level and before singulation. A street 70 between neighboring LED chip regions is illustrated by a vertical dashed line. The street 70 represents a singulation line for separating the LED chip regions into several of the LED chip 66 of FIG. 4A. As illustrated, the electrically conductive via 54 is formed at the street 70. After singulation, the remaining portion of the electrically conductive via 54 is formed along the perimeter sidewall 68 as illustrated by FIG. 4A.

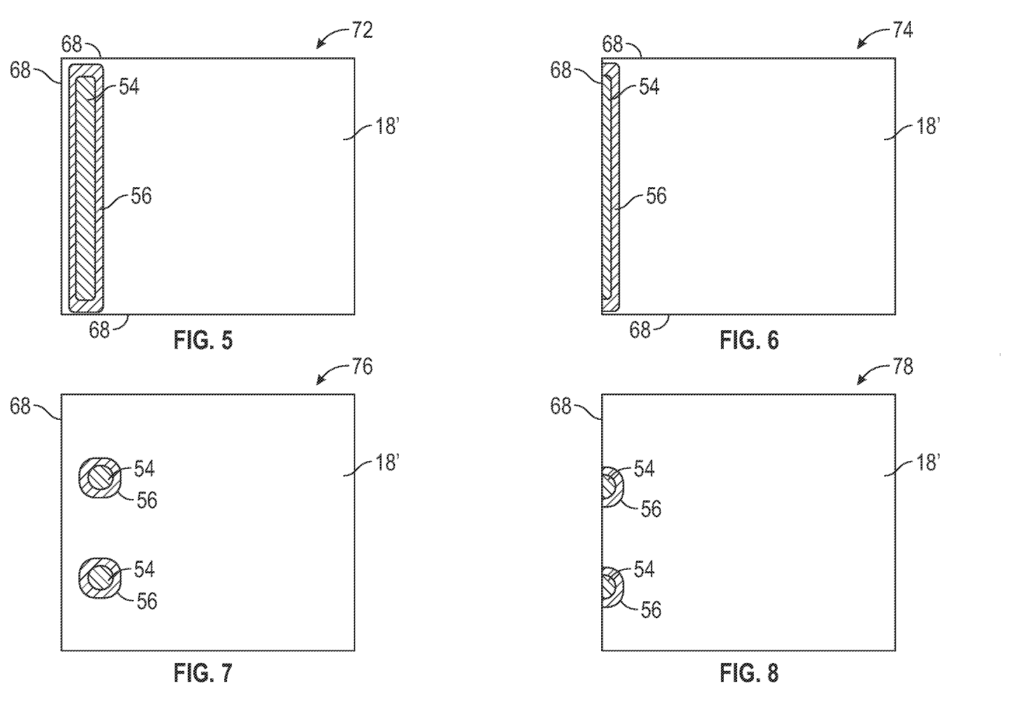

FIGS. 5-8 represent top views of LED chips according to any of the previously described embodiments with respect to FIGS. 1A-4B. In FIGS. 5- 8, the top surface 18’ is shown to represent the light emitting face for the LED chips. A location of the underlying electrically conductive via 54 and the via passivation layer 56 is also shown through corresponding portions of the LED chips. For illustrating purposes only, other elements of the LED chips as described with respect to FIGS. 1A-4B are omitted.

FIG. 5 is a top view of an LED chip 72 that may represent an elongated layout of the electrically conductive via 54 for any of the embodiments described above with respect to FIGS. 1A-3C. As illustrated, the electrically conductive via 54 and the via passivation layer 56 are inset from the perimeter sidewall 68. The electrically conductive via 54 and the via passivation layer 56 may be formed with an elongated shape to provide increased contact area for current flow. The elongated shape may extend in a direction from one perimeter sidewall 68 to another.

FIG. 6 is a top view of an LED chip 74 that may represent an elongated layout of the electrically conductive via 54 for the embodiments described above with respect to FIGS. 4A and 4B. As illustrated, the electrically conductive via 54 and the via passivation layer 56 are formed along the perimeter sidewall 68. As with FIG. 5, the elongated shape may provide increased contact area for current flow. The elongated shape may extend in a direction from one perimeter sidewall 68 to another. By being positioned along the perimeter sidewall 68 in FIG. 6, an increased area for light emissions of the LED chip 74 may be provided.

FIG. 7 is a top view of an LED chip 76 that may represent another layout of the electrically conductive via 54 for any of the embodiments described above with respect to FIGS. 1A-3C. As illustrated, the electrically conductive via 54 and the via passivation layer 56 are inset from the perimeter sidewall 68. The electrically conductive via 54 and the via passivation layer 56 may be formed with a smaller shape as compared with FIG. 5. For example, the electrically conductive via 54 and the via passivation layer 56 may form a generally circular shape. As illustrated, the smaller shape may permit multiple ones of the electrically conductive via 54 and via passivation layer 56. For illustrative purposes, two are drawn, but in practice, any number of electrically conductive vias 54 and corresponding via passivation layers 56 may be provided based on an overall size of the LED chip 76. In certain embodiments, the LED chip 76 may only have a single electrically conductive via 54 and corresponding via passivation layer 56 while providing sufficient current flow.

FIG. 8 is a top view of an LED chip 78 that may represent another layout of the electrically conductive via 54 for the embodiments described above with respect to FIGS. 4A and 4B. In a similar manner as the LED chip 74 of FIG. 6, the electrically conductive via 54 is formed along the perimeter sidewall 68, but with a smaller shape, such as a generally circular shape. The smaller shape may permit multiple ones of the electrically conductive via 54 and via passivation layer 56. For illustrative purposes, two electrically conductive vias 54 are drawn, but in practice, any number of electrically conductive vias 54 and corresponding via passivation layers 56 may be provided based on an overall size of the LED chip 78. In certain embodiments, the LED chip 78 may only have a single electrically conductive via 54 and corresponding via passivation layer 56 while providing sufficient current flow.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) chip, comprising:
a carrier submount comprising a first side and a second side that is opposite the first side;
an active LED structure on first side of the carrier submount, the active LED structure comprising an n-type layer, a p-type layer, and an active layer between the n-type layer and the p-type layer;
a first contact pad on the second side of the carrier submount, the first contact pad electrically coupled to the active LED structure by a first electrically conductive path that includes the carrier submount; and
a second contact pad on the second side of the carrier submount, the second contact pad electrically coupled to the active LED structure by a second electrically conductive path that includes an electrically conductive via extending through the carrier submount.

2. The LED chip of claim 1, further comprising a via passivation layer formed to electrically isolate the electrically conductive via from the carrier submount.

3. The LED chip of claim 2, wherein the via passivation layer forms a first lateral extension between the active LED structure and the carrier submount.

4. The LED chip of claim 3, further comprising one or more bond metal layers between the active LED structure and the carrier submount, the one or more bond metal layers forming a portion of the first electrically conductive path wherein the first lateral extension is formed between the one or more bond metal layers and the electrically conductive via.

5. The LED chip of claim 3, wherein the via passivation layer forms a second lateral extension between the second contact pad and the carrier submount.

6. The LED chip of claim 2, further comprising:
one or more bond metal layers between the active LED structure and the carrier submount, the one or more bond metal layers forming a portion of the first electrically conductive path; and
a passivation layer between the active LED structure and the carrier submount, the electrically conductive via extending through the one or more bond metal layers and the passivation layer.

7. The LED chip of claim 6, wherein the via passivation layer and the passivation layer extend through an opening of the one or more bond metal layers.

8. The LED chip of claim 1, wherein the electrically conductive via forms a first diameter within the carrier submount and a second diameter between the carrier submount and the active LED structure, wherein the second diameter is greater than the first diameter.

9. The LED chip of claim 8, wherein the second diameter is graded from larger to smaller in a direction from the carrier submount to the active LED structure.

10. The LED chip of claim 1, wherein the electrically conductive via is formed along a perimeter sidewall of the carrier submount.

11. The LED chip of claim 1, wherein the electrically conductive via is one of a plurality of electrically conductive vias extending through the carrier submount and electrically coupled to the active LED structure.

12. The LED chip of claim 1, wherein the electrically conductive via forms an elongated shape in a direction from one perimeter sidewall of the LED chip to another perimeter sidewall of the LED chip.

13. A method for fabricating a light-emitting diode (LED) chip, the method comprising:
bonding an active LED structure to a first side of a carrier submount, the active LED structure comprising an n-type layer, a p-type layer, and an active layer between the n-type layer and the p-type layer;
forming a first contact pad on a second side of the carrier submount, the second side being opposite the first side of the carrier submount, the first contact pad being electrically coupled to the active LED structure by a first electrically conductive path that includes the carrier submount;
forming an electrically conductive via through the carrier submount; and
forming a second contact pad on the second side of the carrier submount, the second contact pad electrically coupled to the active LED structure by a second electrically conductive path that includes the electrically conductive via.

14. The method of claim 13, further comprising:
forming a first portion of the electrically conductive via, the first portion being electrically coupled to the active LED structure before bonding the active LED structure to the carrier submount;
forming a second portion of the electrically conductive via in the carrier submount before bonding the active LED structure to the carrier submount; and
electrically coupling the first portion of the electrically conductive via to the second portion of the electrically conductive via when the active LED structure is bonded to the carrier submount.

15. The method of claim 13, wherein bonding the active LED structure to the first side of the carrier submount comprises bonding a first bond metal layer that is on the active LED structure to a second bond metal layer that is on the carrier submount.

16. The method of claim 15, further comprising:
forming a first opening portion in the first bond metal layer before bonding the active LED structure to the carrier submount;
forming a second opening portion in the second bond metal layer before bonding the active LED structure to the carrier submount; and
joining the first opening portion with the second opening portion to form an opening when the active LED structure is bonded to the carrier submount.

17. The method of claim 16, further comprising:
filling the first opening portion with a passivation layer before bonding the active LED structure to the carrier submount; and
filling the second opening portion with the passivation layer before bonding the active LED structure to the carrier submount;
wherein forming the electrically conductive via comprises extending the electrically conductive via through the passivation layer to form the second electrically conductive path.

18. The method of claim 16, wherein:
the opening forms an air gap when the first opening portion and the second opening portion are joined together; and
the electrically conductive via at least partially fills the opening such that the electrically conductive via forms a first diameter within the carrier submount and a second diameter between the carrier submount and the active LED structure, wherein the second diameter is greater than the first diameter.

19. The method of claim 18, further comprising forming a via passivation layer that electrically isolates the electrically conductive via from the carrier submount, the via passivation layer being formed within the opening in a position that is between the electrically conductive via and the first bond metal layer and between the electrically conductive via and the first bond metal layer.

20. The method of claim 13, wherein the electrically conductive via is formed along a perimeter sidewall of the carrier submount.
